(19) United States
(12) Patent Application Publication
(10) Pub. No.: US 2023/0245945 A1
(43) Pub. Date: Aug. 3, 2023

(54) DISCRETE COMPONENT, POWER MODULE AND HEAT SINK SYSTEM

(71) Applicant: FOSHAN NATIONSTAR OPTOELECTRONICS CO., LTD., Foshan (CN)

(72) Inventors: Nianbin Cheng, Foshan (CN); Cheng Li, Foshan (CN); Lifang Liang, Foshan (CN); Yikai Yuan, Foshan (CN); Honggui Zhan, Foshan (CN); Xiangxuan Tan, Foshan (CN)

(73) Assignee: FOSHAN NATIONSTAR OPTOELECTRONICS CO., LTD., Foshan (CN)

(21) Appl. No.: 17/870,932

(22) Filed: Jul. 22, 2022

(30) Foreign Application Priority Data
Dec. 31, 2021 (CN) 202111660198.2

(51) Int. Cl. H01L 23/367; H01L 23/48; H01L 23/495; H01L 29/423; H01L 25/07

(52) U.S. Cl. CPC H01L 23/3675; H01L 23/481; H01L 23/49568; H01L 25/072; H01L 29/42304

(57) ABSTRACT

Provided are a discrete component, a power module and a heat sink system. The discrete component includes a lead frame and a chip. The lead frame includes a top and a bottom disposed adjacent to each other. The top includes a support surface and multiple lateral surfaces connected in sequence. The multiple lateral surfaces are located between the support surface and the bottom. The chip is disposed on each of at least one lateral surface of the multiple lateral surfaces separately. The top of the lead frame is configured to be a metal structure.

### CROSS-REFERENCE TO RELATED APPLICATION(S)

This application claims priority to Chinese Patent Application No. 202111660198.2 filed Dec. 31, 2021, the disclosure of which is incorporated herein by reference in its entirety.

### TECHNICAL FIELD

The present disclosure relates to the technical field of semiconductor devices and, in particular, to a discrete component, a power module and a heat sink system.

### BACKGROUND

A discrete component has the characteristics of small size and flexible and convenient use. With the development of semiconductors, the power of a chip gets increasingly larger, and thus it is a difficult challenge for a discrete component to maintain the advantage of small size while increasing the power density. Subject to the volume of a discrete component, the power density cap of the discrete component is predictable. To break through the problem of the power density ceiling of a discrete component, research on super-power discrete components is carried out.

In the related art, chips of a power device are mounted to a substrate. Since the substrate uses a flat structure, a large number of bonding wires are needed to connect the chips. In the manufacturing process, the chips are mounted, the wires are welded, and then the components are encapsulated by using a stiffer housing. However, an existing discrete component is too small in volume to carry a larger power density. The main reason is that a heat dissipation structure for the discrete component can hardly be implemented in the device having a larger power. Thus, in the related art, it is more selected to encapsulate a power module. The core difference between the module and the device lies in that the module is larger in size so that it can carry more chips, do more work and match a heat sink system having a higher heat dissipation capability.

A device configured to be a three-dimensional structure to increase the power density is also disclosed. For example, Chinese Patent CN201980000324.6 discloses a power converter. The power converter includes a substrate and four side substrates. Each side substrate is provided with a power switch circuit. That is, the multi-side mounting and the heat dissipation are achieved by using the space above the substrate. In this manner, the power density and the heat dissipation density are improved. However, each substrate of the power converter of this structure is relatively independent, leading to a poor resistance to pressure.

### SUMMARY

The present disclosure provides a discrete component, a power module and a heat sink system to solve the problem in which an existing discrete component fails to possess all of the following: small volume, high heat dissipation and high power density.

In a first aspect, a discrete component is provided. The discrete component includes a lead frame and a chip.

The lead frame includes a top and a bottom disposed adjacent to each other. The top includes a support surface and multiple lateral surfaces connected in sequence. The multiple lateral surfaces are located between the support surface and the bottom.

The chip is disposed on each of at least one lateral surface of the multiple lateral surfaces separately.

In a solution of the discrete component, the support surface is provided with a moisture-proof part along the peripheral edge of the support surface.

In a solution of the discrete component, a recess is formed in the each of the at least one lateral surface, and the chip is disposed in the recess.

In a solution of the discrete component, the top includes a first electrode frame, and the bottom includes a second electrode frame and a third electrode frame.

The first electrode frame, the second electrode frame and the third electrode frame are insulated from each other. A first electrode of the chip is connected to the first electrode frame. A second electrode of the chip is connected to the second electrode frame. A third electrode of the chip is connected to the third electrode frame.

In a solution of the discrete component, the second electrode frame and the third electrode frame are at least partially stacked.

In a solution of the discrete component, the second electrode frame is disposed on a surface of the third electrode frame, and the second electrode frame and the third electrode frame are each formed with a via.

A first external terminal of the first electrode frame extends through both the via of the second electrode frame and the via of the third electrode frame and is exposed from the second electrode frame and the third electrode frame.

A second external terminal of the second electrode frame extends through the via of the third electrode frame and is exposed from the third electrode frame.

A third external terminal of the third electrode frame is exposed.

In a solution of the discrete component, the third electrode frame includes a third electrode base and at least two third electrode connection portions disposed on the third electrode base. Two adjacent third electrode connection portions are spaced apart from each other and form empty spaces on the third electrode base.

The second electrode frame includes at least two second electrode connection portions. The at least two second electrode connection portion are disposed in the empty spaces in a one-to-one manner.

In a solution of the discrete component, a first insulating plate is vertically disposed between a second electrode connection portion and a third electrode connection portion adjacent to the second electrode connection portion.

A second insulating plate is horizontally disposed between the first electrode frame and the second electrode frame, between the first electrode frame and the third electrode frame and between the second electrode frame and the third electrode frame separately.

In a solution of the discrete component, the support surface is configured to be a first external terminal, a first part of the second electrode frame and a second part of the third electrode frame are arranged adjacent to each other on the same horizontal plane, the lower surface of the first part is configured to be a second external terminal, and the lower surface of the second part is configured to be a third external terminal.

In a solution of the discrete component, the second electrode frame includes a second electrode base and at least two second electrode connection portions, the at least two second electrode connection portions are connected to the outer periphery of the second electrode base, a height difference is configured between the surface of each second electrode connection portion facing the third electrode frame and the surface of the second electrode base facing the third electrode frame, and empty spaces are formed between two adjacent second electrode connection portions.

The third electrode frame includes a third electrode base and at least two third electrode connection portions, the at least two third electrode connection portions are connected to the outer periphery of the third electrode base, a height difference is configured between the surface of each third electrode connection portion facing the second electrode frame and the surface of the third electrode base facing the second electrode frame.

The second electrode base is stacked on the third electrode base. The at least two third electrode connection portions are disposed in the empty spaces in a one-to-one manner.

In a solution of the discrete component, a first insulating plate is vertically disposed between a second electrode connection portion and a third electrode connection portion adjacent to the second electrode connection portion.

A second insulating plate is horizontally disposed between the second electrode base and the third electrode base, between the first electrode frame and the second electrode frame and between the first electrode frame and the third electrode frame separately.

In a solution of the discrete component, in a first direction defined by each of the at least one lateral surface, the chip is adjacent to one electrode connection portion and one third electrode connection portion, the second electrode of the chip is connected to the outer peripheral surface of the one second electrode connection portion, and the third electrode of the chip is connected to the outer peripheral surface of the one third electrode connection portion.

In a solution of the discrete component, a heat sink is disposed on the support surface.

In a solution of the discrete component, the discrete component also includes a package.

The package covers at least the multiple lateral surfaces.

In a second aspect, a power module is provided. The power module includes the preceding discrete component. The power module also includes a circuit board; an encapsulation housing; an encapsulation body and a connection terminal.

The discrete component is disposed on the circuit board.

The circuit board is disposed within the encapsulation housing. The discrete component is at least partially built in the encapsulation housing.

The encapsulation body is configured to pot the circuit board. The discrete component is partially exposed from the encapsulation body.

The connection terminal is disposed on the circuit board. One end of the connection terminal is connected to the circuit board. Another end of the connection terminal extends out of the encapsulation housing.

In a third aspect, a heat sink system is provided. The heat sink system includes the preceding power module. The heat sink system also includes a heat sink assembly.

At least one power module is disposed on the heat sink assembly. A heat sink chamber is disposed within the heat sink assembly. Several heat sink bars are disposed within the heat sink chamber. An inlet is disposed at one end of the heat sink chamber. An outlet is disposed at another end of the heat sink chamber. A heat sink runner is defined among the heat sink bars and between the inlet and the outlet.

### BRIEF DESCRIPTION OF DRAWINGS

FIG. 1 is a view illustrating the structure of a discrete component according to embodiment one, embodiment two and embodiment three of the present application.

FIG. 2 is a schematic view of part of the lead frame of the discrete component of FIG. 1.

FIG. 3 is an exploded view of the discrete component of FIG. 1.

FIG. 4 is a view illustrating the structure of the discrete component of FIG. 3 in which a second electrode frame cooperates with a third electrode frame.

FIG. 5 is a view illustrating the structure of a discrete component according to embodiment four of the present application.

FIG. 6 is an exploded view of the discrete component of FIG. 5.

FIG. 7 is an exploded view of the bottom of the discrete component of FIG. 5.

FIG. 8 is an exploded view of a discrete component according to embodiment five of the present application.

FIG. 9 is a view illustrating the structure of a discrete component according to embodiment six of the present application.

FIG. 10 is a view illustrating the structure of a power module according to embodiment seven of the present application.

FIG. 11 is an exploded view of the power module of FIG. 10.

FIG. 12 is a view illustrating the structure of a power module according to embodiment eight of the present application.

FIG. 13 is a view illustrating the structure of a heat sink system according to embodiment nine of the present application.

FIG. 14 is an exploded view of the heat sink system of FIG. 13.

FIG. 15 is a view illustrating the structure of a heat sink system according to embodiment ten of the present application.

FIG. 16 is an exploded view of the heat sink system of FIG. 15.

Reference list

| | |
|---|---|
| 1 | lead frame |
| 2 | chip |
| 3 | heat sink |
| 4 | package |
| 10 | support surface |
| 11 | lateral surface |
| 12 | recess |
| 100 | moisture-proof part |
| 101 | first electrode frame |
| 101A | first external terminal |
| 102 | second electrode frame |
| 102A | second external terminal |
| 103 | third electrode frame |
| 103A | third external terminal |
| 104 | first isolating plate |
| 105 | second isolating plate |
| 106 | third isolating plate |
| 1020 | second electrode base |
| 1021 | second electrode connection portion |
| 1030 | third electrode base |
| 1031 | third electrode connection portion |
| 200 | circuit board |
| 300 | encapsulation housing |
| 301 | connection terminal |
| 400 | heat sink assembly |
| 401 | heat sink bar |
| 402 | inlet |
| 403 | outlet |
| 4001 | heat sink box |
| 4002 | cover plate |

### DETAILED DESCRIPTION

The present disclosure is described hereinafter in detail in conjunction with drawings and embodiments. It is to be understood that the embodiments described herein are intended to explain the present disclosure and not to limit the present disclosure. Additionally, it is to be noted that for ease of description, only part, not all, of the structures related to the present disclosure are illustrated in the drawings.

In the description of the present disclosure, unless otherwise expressly specified and limited, the term “connected to each other”, “connected” or “secured” is to be construed in a broad sense, for example, as securely connected, detachably connected or integrated; mechanically connected or electrically connected; directly connected to each other or indirectly connected to each other via an intermediary; or internally connected between two components or interaction relations between two components. For those of ordinary skill in the art, meanings of the preceding terms in the present disclosure may be understood based on situations.

In the present disclosure, unless otherwise expressly specified and limited, when a first feature is described as “above” or “below” a second feature, the first feature and the second feature may be in direct contact or be in contact via another feature between the two features. Moreover, when the first feature is described as “on”, “above”, or “over” the second feature, the first feature is right on, above, or over the second feature or the first feature is obliquely on, above, or over the second feature, or the first feature is simply at a higher level than the second feature. When the first feature is described as “under”, “below”, or “underneath” the second feature, the first feature is right under, below, or underneath the second feature or the first feature is obliquely under, below, or underneath the second feature, or the first feature is simply at a lower level than the second feature.

In the description of this embodiment, the orientation or position relationships indicated by terms such as “above”, “below”, and “right” are based on the orientation or position relationships shown in the drawings, merely for ease of description and simplifying an operation, and these relationships do not indicate or imply that the referred device or element has an orientation and is constructed and operated in an orientation, and thus it is not to be construed as limiting the present disclosure. In addition, the terms “first” and “second” are used only to distinguish between descriptions and have no special meaning.

### Embodiment One

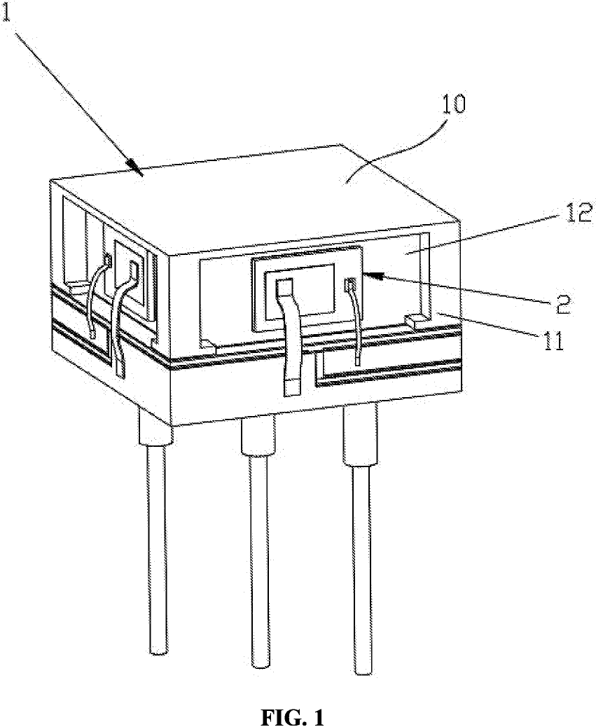

Embodiment one provides a discrete component. As shown in FIG. 1, the discrete component includes a lead frame 1 and a chip 2.

In this embodiment of the present application, the lead frame 1 is configured to be a hexahedral structure. In an embodiment, the lead frame 1 is configured to be a cuboidal structure. The lead frame 1 may also be configured to be a structure having more surfaces, such as a heptahedron or an octahedron. The lead frame 1 needs to have a top surface, a bottom surface and at least three lateral surfaces. For example, in the case where the lead frame 1 is a heptahedral structure, the lead frame 1 may still have one top surface and one bottom surface, and the difference is that the lead frame 1 includes five lateral surfaces.

The lead frame 1 includes a top and a bottom disposed adjacent to each other. In an embodiment, the top is configured to be an integral metal structure. The top is not limited to a solid cuboid or a hollow cuboid. In this embodiment of the present application, both the top and the bottom are made of metal copper. In addition, the top of the lead frame 1 may also be made of copper-zinc alloy or copper-aluminum alloy. The metal material of the lead frame 1 is not limited to the preceding materials and may be another material as long as the material satisfies electrical conductivity, thermal conductivity and a certain mechanical strength.

The top is provided with a support surface 10 and four lateral surfaces 11 connected in sequence. The support surface 10 can withstand a certain pressure. The four lateral surfaces 11 are located between the support surface 10 and the bottom. On each of at least one lateral surface 11, at least one chip 2 is disposed.

It is to be noted that in this embodiment of the present application, the four lateral surfaces 11 of the lead frame 1 are perpendicular to the support surface 10. However, the included angle between each of the four lateral surfaces 11 and the support surface 10 is not limited by this embodiment of the present application. That is, the included angle between each of the four lateral surfaces 11 and the support surface 10 may not be 90°. For example, the lead frame 1 may be configured to be a frustum in which an acute angle such as 60° or an obtuse angle such as 120° is formed between each of the four lateral surfaces 11 and the support surface 10.

The lead frame 1 is provided with multiple lateral surfaces 11 along the periphery of the top, and a chip 2 is disposed on each of the at least one lateral surface 11 separately, so that more chips 2 are provided, and the chip integration density is increased. The top of the lead frame 1 is configured to be a metal structure so that heat can be quickly conducted by the chip 2 and dissipated. Moreover, the top of the lead frame 1 is configured to be an integral metal structure and is provided with the support surface 10 so that the lead frame 1 possesses a relatively stable support performance and is not easily deformed by pressure. Therefore, the discrete component is characterized by small size, large chip integration density, high heat dissipation and strong support performance.

This embodiment is based on a discrete component and aims to increase the number of the chips mounted in the discrete component, thereby increasing the power density. Moreover, combined with a special structure, the discrete component can also match a system having a higher heat dissipation capability, and thus can be lightweight and handy and can be stable when operated.

### Embodiment Two

Embodiment two provides a discrete component. Referring to FIG. 1, the discrete component includes a lead frame 1 and a chip 2.

In this embodiment of the present application, the lead frame 1 is configured to be a hexahedral structure. In an embodiment, the lead frame 1 is configured to be a cuboidal structure. The lead frame 1 may also be configured to be a structure having more surfaces, such as a heptahedron or an octahedron. The lead frame 1 needs to have a top surface, a bottom surface and at least three lateral surfaces. For example, in the case where the lead frame 1 is the heptahedral structure, the lead frame 1 may still have one top surface and one bottom surface, and the difference is that the lead frame 1 includes five lateral surfaces.

The lead frame 1 includes a top and a bottom disposed adjacent to each other. In an embodiment, the top is configured to be an integral metal structure. The top is not limited to a solid cuboid or a hollow cuboid. In this embodiment of the present application, both the top and the bottom are made of metal copper. In addition, the top of the lead frame 1 may also be made of copper-zinc alloy or copper-aluminum alloy. The metal material of the lead frame 1 is not limited to the preceding materials and may be another material as long as the material satisfies the electrical conductivity, thermal conductivity and a certain mechanical strength.

The top is provided with a support surface 10 and four lateral surfaces 11 connected in sequence. The support surface 10 can withstand a certain pressure. The four lateral surfaces 11 are located between the support surface 10 and the bottom. On each of at least one lateral surface 11, at least one chip 2 is disposed.

It is to be noted that in this embodiment of the present application, the four lateral surfaces 11 of the lead frame 1 are perpendicular to the support surface 10. However, the included angle between each of the four lateral surfaces 11 and the support surface 10 is not limited by this embodiment of the present application. That is, the included angle between each of the four lateral surfaces 11 and the support surface 10 may not be 90°. For example, the lead frame 1 may be configured to be a frustum in which an acute angle such as 60° or an obtuse angle such as 120° is formed between each of the four lateral surfaces 11 and the support surface 10.

The lead frame 1 is provided with multiple lateral surfaces 11 along the periphery of the top, and a chip 2 is disposed on each of the at least one lateral surface 11 separately, so that more chips 2 are provided, and the chip integration density is increased. The top of the lead frame 1 is configured to be a metal structure so that heat can be quickly conducted by the chip 2 and dissipated. Moreover, the top of the lead frame 1 is configured to be an integral metal structure and is provided with the support surface 10 so that the lead frame 1 possesses a relatively stable support performance and is not easily deformed by pressure. Therefore, the discrete component is characterized by small size, large chip integration density, high heat dissipation and strong support performance.

In an embodiment, the mode of connection between the chip 2 and each lateral surface 11 is not limited to welding or wire bonding.

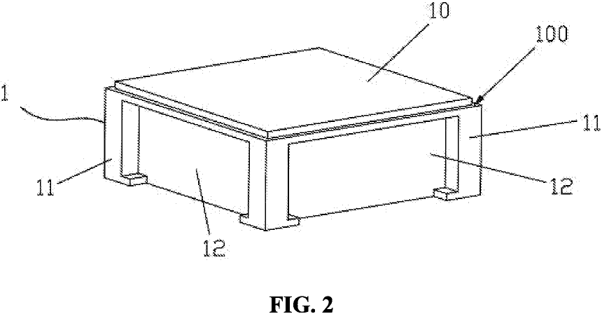

As shown in FIGS. 1 and 2, each lateral surface 11 is provided with at least one recess 12, and at least one chip 2 is disposed in each recess 12. In other words, the chip on each lateral surface 11 is disposed within the recess 12.

The chip 2 is disposed in the recess 12 so that the arc height of the bonding wire and the volume of the discrete component can be reduced, and moreover, the number of heat dissipation surfaces of the lead frame 1 is increased and the heat dissipation area of the lead frame 1 is increased, facilitating a higher heat dissipation capability.

It is to be noted that in this embodiment of the present application, the recess 12 is configured to be a rectangle, the length of the rectangle is greater than the length of the chip 2, and the width of the rectangle is greater than the width of the chip 2. When the chip 2 is disposed in the recess 12, a predetermined distance is configured between each edge of the recess 12 and the chip 2. The predetermined distance may be determined according to the actual process. On the one hand, the predetermined distance configured between each edge of the recess 12 and the chip 2 makes it easier to place the chip 2. On the other hand, the predetermined distance can form a larger heat dissipation gap, facilitating heat dissipation of the discrete component.

It is to be noted that the recess 12 may also be configured to be in other shapes such as a circle and an oval, and the shape of the recess 12 is not limited by this embodiment of the present application.

FIG. 2 is a schematic view of part of the lead frame of the discrete component of FIG. 1. As shown in FIG. 2, the support surface 10 is provided with a moisture-proof part 100 along the peripheral edge of the support surface 10. That is, the moisture-proof part 100 extends along the peripheral edge of the upper surface of the lead frame 1 to form a quadrangle, and the support surface 10 is located within the peripheral edge of the moisture-proof part 100. The moisture-proof part can extend the path along which water vapor enters each lateral surface 11, thereby preventing the water vapor from infiltrating into the chip 2 and playing a waterproof role for the chip 2.

It is to be noted that the shape of the moisture-proof part 100 is not limited to a quadrangle. For example, the moisture-proof part 100 may also be configured to be in other shapes such as a circle, a hexagon and an octagon.

In this embodiment of the present application, the lead frame 1 is wrapped with a package 4, and the package 4 covers at least the multiple lateral surfaces 11 to seal the chip 2 within the recess 12 of each lateral surface 11. The package 4 can insulate and protect the chip 2 to increase the integrity and stability of the three-dimensional discrete component.

In this embodiment, the package 4 extends to each edge of the support surface 10 and fully covers the moisture-proof part 100. With such design, the strength of bonding between the package 4 and the lead frame 1 can be enhanced.

### Embodiment Three

Embodiment three provides a discrete component. As shown in FIG. 1, the discrete component includes a lead frame 1 and a chip 2.

In this embodiment of the present application, the lead frame 1 is configured to be a hexahedral structure. In an embodiment, the lead frame 1 is configured to be a cuboidal structure. The lead frame 1 may also be configured to be a structure having more surfaces, such as a heptahedron or an octahedron. The lead frame 1 needs to have a top surface, a bottom surface and at least three lateral surfaces. For example, in the case where the lead frame 1 is the heptahedral structure, the lead frame 1 may still have one top surface and one bottom surface, and the difference is that the lead frame 1 includes five lateral surfaces.

The lead frame 1 includes a top and a bottom disposed adjacent to each other. In an embodiment, the top is configured to be an integral metal structure. The top is not limited to a solid cuboid or a hollow cuboid. In this embodiment of the present application, both the top and the bottom are made of metal copper. In addition, the top of the lead frame 1 may also be made of copper-zinc alloy or copper-aluminum alloy. The metal material of the lead frame 1 is not limited to the preceding materials and may be another material as long as the material satisfies the electrical conductivity, thermal conductivity and a certain mechanical strength.

The top is provided with a support surface 10 and four lateral surfaces 11 connected in sequence. The support surface 10 can withstand a certain pressure. The four lateral surfaces 11 are located between the support surface 10 and the bottom. On each of at least one lateral surface 11, at least one chip 2 is disposed.

It is to be noted that in this embodiment of the present application, the four lateral surfaces 11 of the lead frame 1 are perpendicular to the support surface 10. However, the included angle between each of the four lateral surfaces 11 and the support surface 10 is not limited by this embodiment of the present application. That is, the included angle between each of the four lateral surfaces 11 and the support surface 10 may not be 90°. For example, the lead frame 1 may be configured to be a frustum in which an acute angle such as 60° or an obtuse angle such as 120° is formed between each of the four lateral surfaces 11 and the support surface 10.

The lead frame 1 is provided with multiple lateral surfaces 11 along the periphery of the top, and a chip 2 is disposed on each of the at least one lateral surface 11 separately, so that more chips 2 are provided, and the chip integration density is increased. The top of the lead frame 1 is configured to be a metal structure so that heat can be quickly conducted by the chip 2 and dissipated. Moreover, the top of the lead frame 1 is configured to be an integral metal structure and is provided with the support surface 10 so that the lead frame 1 possesses a relatively stable support performance and is not easily deformed by pressure. Therefore, the discrete component is characterized by small size, large chip integration density, high heat dissipation and strong support performance.

In an embodiment, the mode of connection between the chip 2 and each lateral surface 11 is not limited to welding or wire bonding.

In an embodiment, each lateral surface 11 is provided with at least one recess 12, and at least one chip 2 is disposed in each recess 12. In other words, the chip on each lateral surface 11 is disposed within the recess 12.

The chip 2 is disposed in the recess 12 so that the arc height of the bonding wire and the volume of the discrete component can be reduced, and moreover, the number of heat dissipation surfaces of the lead frame 1 is increased and the heat dissipation area of the lead frame 1 is increased, facilitating a higher heat dissipation capability.

It is to be noted that in this embodiment of the present application, the recess 12 is configured to be a rectangle, the length of the rectangle is greater than the length of the chip 2, and the width of the rectangle is greater than the width of the chip 2. When the chip 2 is disposed in the recess 12, a predetermined distance is configured between each edge of the recess 12 and the chip 2. The predetermined distance may be determined according to the actual process. On the one hand, the predetermined distance configured between each edge of the recess 12 and the chip 2 makes it easier to place the chip 2. On the other hand, the predetermined distance can form a larger heat dissipation gap, facilitating heat dissipation of the discrete component.

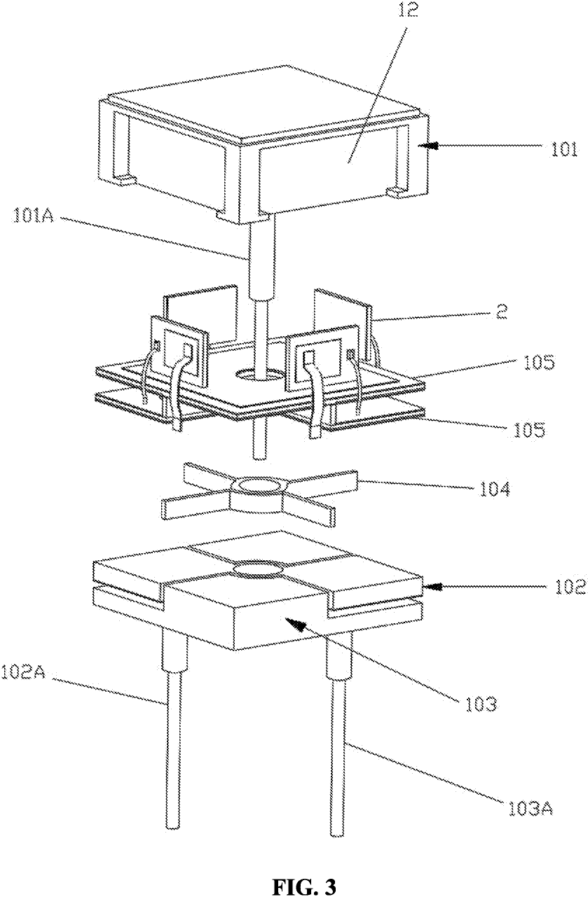

FIG. 3 is an exploded view of the discrete component in embodiment three of the present application. The top includes a first electrode frame 101, and the bottom includes a second electrode frame 102 and a third electrode frame 103. In this embodiment of the present application, the second electrode frame 102 and the third electrode frame 103 are both configured to be made of the same metal material as the first electrode frame 101, the second electrode frame 102 and the third electrode frame 103 are both disposed below the first electrode frame 101, and the first electrode frame 101, the second electrode frame 102 and the third electrode frame 103 are insulated from each other. In this embodiment of the present application, the first electrode frame 101 is connected to a first electrode of the chip 2, the second electrode frame 102 is connected to a second electrode of the chip 2, and the third electrode frame 103 is connected to a third electrode of the chip 2.

It is to be noted that the first electrode frame 101, the second electrode frame 102 and the third electrode frame 103 are connected to different electrodes of the chip 2, and which electrode of the chip 2 is connected to which one of the first electrode frame 101, the second electrode frame 102 or the third electrode frame 103 is not limited by this embodiment of the present application.

In this embodiment of the present application, the second electrode frame 102 is fully stacked on a surface of the third electrode frame 103, and both the second electrode frame 102 and the third electrode frame 103 are disposed below the first electrode frame 101. It may be understood that the second electrode frame 102 and the third electrode frame 103 form a nested structure, the first electrode frame 101, the second electrode frame 102 and the third electrode frame 103 constitute the lead frame 1 into a multi-layer structure in a vertical direction.

It is to be noted that the first electrode frame 101, the second electrode frame 102 and the third electrode frame 103 are configured to be made of the same material such as metal copper or copper-zinc alloy.

The first electrode frame 101 has the preceding four lateral surfaces 11 and the preceding support surface 10. Correspondingly, the four lateral surfaces 11 of the first electrode frame 101 are each provided with one recess 12, at least one chip 2 is disposed in each recess 12, the second electrode of the chip 2 is connected to the second electrode frame 102, and the third electrode of the chip 2 is connected to the third electrode frame 103.

Both the second electrode frame 102 and the third electrode frame 103 are disposed below the first electrode frame 101 so that the lead frame 1 is vertically disposed, the occupation area of the discrete component is reduced, more chips 2 are provided, and the integration density of the chips 2 is increased.

In an embodiment, in this embodiment of the present application, the second electrode frame 102 is fully nested on the third electrode frame 103 so that the second electrode frame 102 and the third electrode frame 103 are combined into one cuboidal structure and can be disposed below the first electrode frame 101. It is to be noted that the combined structure of the second electrode frame 102 and the third electrode frame 103 is just adapted to the structure of the first electrode frame. That is, the first electrode frame is a cuboidal structure, and the combined structure of the second electrode frame 102 and the third electrode frame 103 is a cuboidal structure having the same size as the first electrode frame.

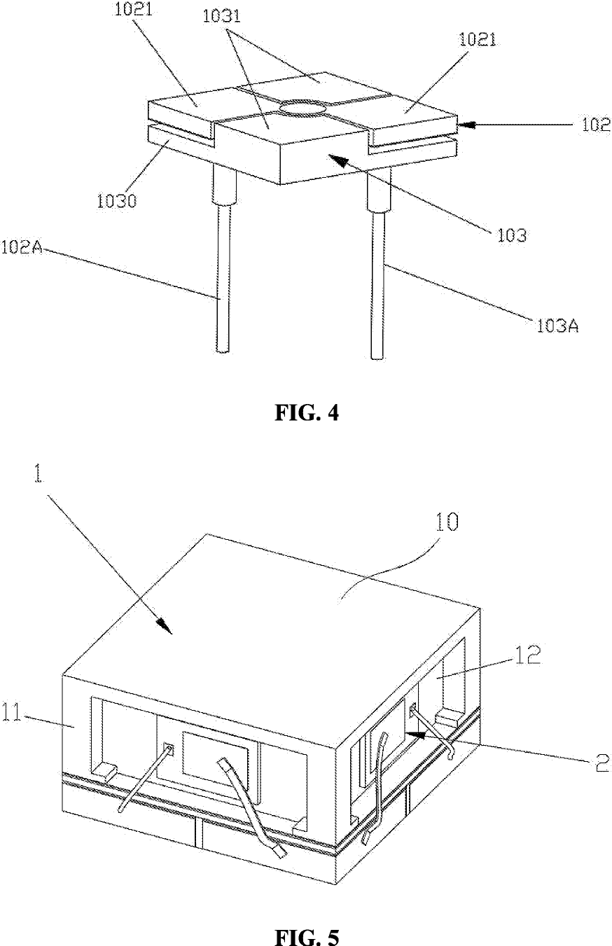

FIG. 4 is a view illustrating part of the structure of FIG. 3. The third electrode frame 103 includes a third electrode base 1030 and at least two third electrode connection portions 1031 disposed on the third electrode base 1030. The at least two third electrode connection portions 1031 are in one-to-one correspondence with the chips 2. Here, the one-to-one correspondence means that the chip 2 in each of the four directions can be connected downward to one third electrode connection portion 1031.

Two adjacent third electrode connection portions 1031 are spaced apart from each other and form empty spaces. A second electrode connection portion 102 of the second electrode frame 102 is disposed in each empty space. One chip 2 is connected to one set composed of one third electrode connection portion 1031 and one second electrode connection portion 1021 adjacent to each other.

In this embodiment of the present application, the third electrode frame 103 includes the third electrode base 1030 and two third electrode connection portions 1031 disposed on the third electrode base 1030. It is to be noted that the third electrode frame 103 is an integrally formed structure, that is, the third electrode base 1030 is secured to the two third electrode connection portions 1031.

Both the two third electrode connection portions 1031 are configured to be a rectangle and are diagonally disposed, the shape of the outer periphery of the third electrode base 1030 is also rectangular and is same as the shape of the outer periphery of the first electrode frame 101, and the third electrode base 1030 forms two rectangular empty spaces outside the two third electrode connection portions 1031.

The second electrode frame 102 includes two second electrode connection portions 1021. The two second electrode connection portions 1021 are disposed in two empty spaces in a one-to-one manner. In this manner, the second electrode frame 102 and the third electrode frame 103 are combined into a structure in the shape of the Chinese character “tian” [symbol] and at any edge of the structure in the shape of the Chinese character “tian” [symbol] one second electrode connection portion 1021 and one third electrode connection portion 1031 are disposed. In other words, each edge of the combined structure can be connected to the second electrode and the third electrode of a corresponding chip 2.

It is to be noted that the second electrode frame 102 is an integrally formed structure. That is, the two second electrode connection portions 1021 are secured.

The third electrode connection portions 1031 are disposed on the third electrode base 1030. The empty spaces are formed between two adjacent third electrode connection portions 1031 and are configured to accommodate the second electrode connection portions 1031. In this manner, the second electrode frame 102 is mounted on the third electrode base 1030, and the second electrode frame 102 and the third electrode frame 103 form a structure having a uniform height, and the second electrode frame 102 and the third electrode frame 103 are connected on the same layer.

In an embodiment, the second electrode frame 102 is disposed on a surface of the third electrode frame 103. The second electrode frame 102 and the third electrode frame 103 are each formed with a via. A first external terminal 101A of the first electrode frame 101 extends through both the via of the second electrode frame 102 and the via of the third electrode frame 103 and is exposed from the second electrode frame 102 and the third electrode frame 103. A second external terminal 102A of the second electrode frame 102 extends through the via of the third electrode frame 103 and is exposed from the third electrode frame 103. A third external terminal 103A of the third electrode frame 103 is exposed. It is to be noted that in this embodiment of the present application, the first external terminal 101A, the second external terminal 102A and the third external terminal 103A are each configured to be a pin.

The second electrode frame 102 and the third electrode frame 103 are stacked up and down to reduce the height of the discrete component. The second electrode frame 102 and the third electrode frame 103 are each formed with the via to give way to the first external terminal 101A of the first electrode frame 101 and the second external terminal 102A of the second electrode frame 102 to ensure the conduction efficiency of the chip so that the performance synchronization is error-free, and a short circuit is avoided.

In an embodiment, the center of the combined structure of the second electrode frame 102 and the third electrode frame 103 is formed with one via for the first external terminal 101A of the first electrode frame 101 to extend through, each of at least one empty space of the third electrode base 1030 of the third electrode frame 103 is formed with one via for the second external terminal 102A of the second electrode frame 102 to extend through, and moreover, the bottom surface of the third electrode base 1030 is provided with one third external terminal 103A.

In an embodiment, a first insulating plate 104 is vertically disposed between a second electrode connection portion 1021 and a third electrode connection portion 1031 adjacent to the second electrode connection portion 1021. In this embodiment of the present application, the first insulating plate 104 is in a cross-shaped structure, and each of the four spacers of the cross-shaped structure spaces apart a second electrode connection portion 1021 and a third electrode connection portion 1031 adjacent to the second electrode connection portion 1021.

In an embodiment, a second insulating plate 105 is horizontally disposed between the first electrode frame 101 and the second electrode frame 102, between the first electrode frame 101 and the third electrode frame 103 and between the second electrode frame 102 and the third electrode frame 103 separately.

The first insulating plate 104 is inserted between a second electrode connection portion 1021 and a third electrode connection portion 1031 adjacent to each other so that the second electrode connection portion 1021 and the third electrode connection portion 1031 do not conduct electricity to each other and are insulated from each other. The second insulating plate 105 ensures that the electrode frames do not conduct electricity to each other and are insulated from each other.

As shown in FIG. 3, one large second insulating plate 105 and two small second insulating plates 105 are provided. The one large second insulating plate 105 is disposed on the upper surface of the combined structure of the second electrode frame 102 and the third electrode frame 103. After the second electrode frame 102 and the third electrode frame 103 are combined, the upper surface of the second electrode frame 102 is on the same plane as the upper surface of the third electrode frame 103; therefore, the arrangement in which the area of the second insulating plate 105 disposed below the first electrode frame 101 is the same as the area of the bottom surface of the first electrode frame 101 makes the second insulating plate 105 disposed below the first electrode frame 101 exactly cover the second electrode frame 102 and the third electrode frame 103. The two small second insulating plates 105 are disposed below the two second electrode connection portions 1021 in a one-to-one manner. That is, the total area of the two small second insulating plates 105 between the second electrode frame 102 and the third electrode frame 103 is the same as the area of the bottom surface of the second electrode frame 102.

In this embodiment of the present application, both the first insulating plate 104 and the second insulating plate 105 are made of an aluminum nitride material or a silicon nitride material.

As shown in FIG. 2, the support surface 10 is provided with a moisture-proof part 100 along the peripheral edge of the support surface 10. That is, the moisture-proof part 100 extends along the peripheral edge of the upper surface of the lead frame 1 to form a quadrangle, and the support surface 10 is located within the peripheral edge of the moisture-proof part 100. The moisture-proof part can extend the path along which water vapor enters each lateral surface 11, thereby preventing the water vapor from infiltrating into the chip 2 and playing a waterproof role for the chip 2.

It is to be noted that the shape of the moisture-proof part 100 is not limited to a quadrangle. For example, the moisture-proof part 100 may also be configured to be in other shapes such as a circle, a hexagon and an octagon.

In this embodiment of the present application, the lead frame 1 is wrapped with a package 4, and the package 4 covers at least the multiple lateral surfaces 11 to seal the chip 2 within the recess 12 of each lateral surface 11. The package 4 can insulate and protect the chip 2 to increase the integrity and stability of the three-dimensional discrete component. In addition, the package 4 can fix the dispersed first electrode frame 101, second electrode frame 102 and third electrode frame 103 as a whole.

In this embodiment, the package 4 extends to each edge of the support surface 10 and fully covers the moisture-proof part 100. With such design, the strength of bonding between the package 4 and the lead frame 1 can be enhanced.

### Embodiment Four

Embodiment four provides a discrete component. As shown in FIG. 5, the discrete component includes a lead frame 1 and a chip 2.

In this embodiment of the present application, the lead frame 1 is configured to be a hexahedral structure. In an embodiment, the lead frame 1 is configured to be a cuboidal structure. The lead frame 1 may also be configured to be a structure having more surfaces, such as a heptahedron or an octahedron. The lead frame 1 needs to have a top surface, a bottom surface and at least three lateral surfaces. For example, in the case where the lead frame 1 is the heptahedral structure, the lead frame 1 may still have one top surface and one bottom surface, and the difference is that the lead frame 1 includes five lateral surfaces.

The lead frame 1 includes a top and a bottom disposed adjacent to each other. In an embodiment, the top is configured to be an integral metal structure. The top is not limited to a solid cuboid or a hollow cuboid. In this embodiment of the present application, both the top and the bottom are made of metal copper. In addition, the top of the lead frame 1 may also be made of copper-zinc alloy or copper-aluminum alloy. The metal material of the lead frame 1 is not limited to the preceding materials and may be another material as long as the material satisfies the electrical conductivity, thermal conductivity and a certain mechanical strength.

The top is provided with a support surface 10 and four lateral surfaces 11 connected in sequence. The support surface 10 can withstand a certain pressure. The four lateral surfaces 11 are located between the support surface 10 and the bottom. On each of at least one lateral surface 11, at least one chip 2 is disposed.

It is to be noted that in this embodiment of the present application, the four lateral surfaces 11 of the lead frame 1 are perpendicular to the support surface 10. However, the included angle between each of the four lateral surfaces 11 and the support surface 10 is not limited by this embodiment of the present application. That is, the included angle between each of the four lateral surfaces 11 and the support surface 10 may not be 90°. For example, the lead frame 1 may be configured to be a frustum in which an acute angle such as 60° or an obtuse angle such as 120° is formed between each of the four lateral surfaces 11 and the support surface 10.

The lead frame 1 is provided with multiple lateral surfaces 11 along the periphery of the top, and a chip 2 is disposed on each of the at least one lateral surface 11 separately, so that more chips 2 are provided, and the chip integration density is increased. The top of the lead frame 1 is configured to be a metal structure so that heat can be quickly conducted by the chip 2 and dissipated. Moreover, the top of the lead frame 1 is configured to be an integral metal structure and is provided with the support surface 10 so that the lead frame 1 possesses a relatively stable support performance and is not easily deformed by pressure. Therefore, the discrete component is characterized by small size, large chip integration density, high heat dissipation and strong support performance.

In an embodiment, the mode of connection between the chip 2 and each lateral surface 11 is not limited to welding or wire bonding as long as the chip 2 is fixed to each lateral surface 11.

In an embodiment, each lateral surface 11 is provided with one recess 12, and at least one chip 2 is disposed in each recess 12. In other words, the chip on each lateral surface 11 is disposed within the recess 12.

The chip 2 is disposed in the recess 12 so that the arc height of the bonding wire and the volume of the discrete component can be reduced, and moreover, the number of heat dissipation surfaces of the lead frame 1 is increased and the heat dissipation area of the lead frame 1 is increased, facilitating a higher heat dissipation capability.

It is to be noted that in this embodiment of the present application, the recess 12 is configured to be a rectangle, the length of the rectangle is greater than the length of the chip 2, and the width of the rectangle is greater than the width of the chip 2. When the chip 2 is disposed in the recess 12, a predetermined distance is configured between each edge of the recess 12 and the chip 2. The predetermined distance may be determined according to the actual process. On the one hand, the predetermined distance configured between each edge of the recess 12 and the chip 2 makes it easier to place the chip 2. On the other hand, the predetermined distance can form a larger heat dissipation gap, facilitating heat dissipation of the discrete component.

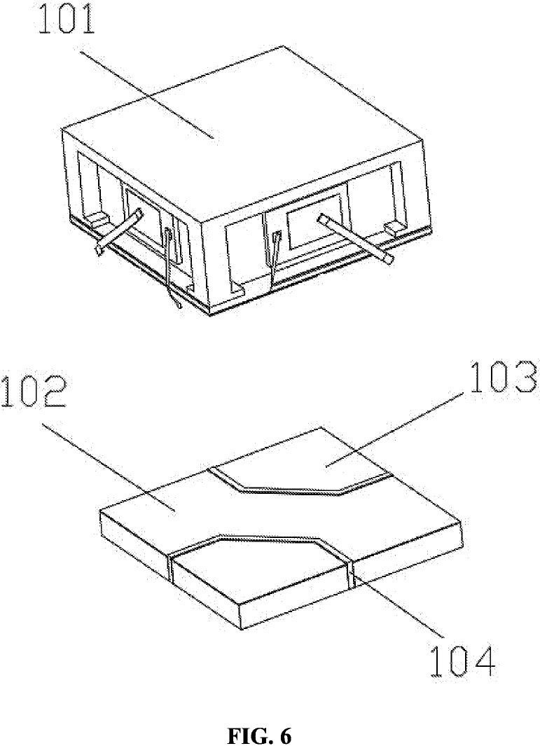

FIG. 6 is an exploded view of the discrete component in embodiment five of the present application. The top includes a first electrode frame 101, and the bottom includes a second electrode frame 102 and a third electrode frame 103. In this embodiment of the present application, the second electrode frame 102 and the third electrode frame 103 are both configured to be made of the same metal material as the first electrode frame 101, the second electrode frame 102 and the third electrode frame 103 are both disposed below the first electrode frame 101, and the first electrode frame 101, the second electrode frame 102 and the third electrode frame 103 are insulated from each other. In this embodiment of the present application, the first electrode frame 101 is connected to a first electrode of the chip 2, the second electrode frame 102 is connected to a second electrode of the chip 2, and the third electrode frame 103 is connected to a third electrode of the chip 2.

It is to be noted that the first electrode frame 101, the second electrode frame 102 and the third electrode frame 103 are connected to different electrodes of the chip 2, and which electrode of the chip 2 is connected to which one of the first electrode frame 101, the second electrode frame 102 or the third electrode frame 103 is not limited by this embodiment of the present application.

In this embodiment of the present application, the second electrode frame 102 and the third electrode frame 103 are partially stacked, and both the second electrode frame 102 and the third electrode frame 103 are disposed below the first electrode frame 101. That is, the first electrode frame 101, the second electrode frame 102 and the third electrode frame 103 form a vertically multi-layered structure that constitutes the lead frame 1.

In this embodiment, the support surface 10 is configured to be the first external terminal, the second electrode frame 102 and the third electrode frame 103 are nested in each other on the same horizontal plane, and the lower surface of the second electrode frame 102 and the lower surface of the third electrode frame 103 are configured to be the second external terminal and the third external terminal respectively. The support surface 10 is used as the first external terminal, and the lower surface of the second electrode frame 102 and the lower surface of the third electrode frame 103 are configured to be the second external terminal and the third external terminal respectively, so that the three external terminals in embodiment three can be cancelled, and the surfaces of the first electrode frame, the second electrode frame and the third electrode frame are used as pads, so that the height of the discrete component can be reduced.

It is to be noted that the first electrode frame 101, the second electrode frame 102 and the third electrode frame 103 are all configured to be made of the same material such as metal copper or copper-zinc alloy.

The first electrode frame 101 has the preceding four lateral surfaces 11 and the preceding support surface 10. Correspondingly, the four lateral surfaces 11 of the first electrode frame 101 are each provided with one recess 12, at least one chip 2 is disposed in each recess 12, the second electrode of the chip 2 is connected to the second electrode frame 102, and the third electrode of the chip 2 is connected to the third electrode frame 103.

Both the second electrode frame 102 and the third electrode frame 103 are disposed below the first electrode frame 101 so that the lead frame 1 is vertically disposed, the occupation area of the discrete component is reduced, more chips 2 are provided, and the integration density of the chips 2 is increased.

In an embodiment, in this embodiment of the present application, the second electrode frame 102 and the third electrode frame 103 are adjacently disposed in the same layer, another part of the second electrode frame 102 and the third electrode frame 103 are stacked in a height direction so that the second electrode frame 102 and the third electrode frame 103 are combined into one cuboidal structure and can be disposed below the first electrode frame 101. It is to be noted that the combined structure of the second electrode frame 102 and the third electrode frame 103 is just adapted to the structure of the first electrode frame. That is, the first electrode frame is a cuboidal structure, and the combined structure of the second electrode frame 102 and the third electrode frame 103 is a cuboidal structure having the same size as the first electrode frame.

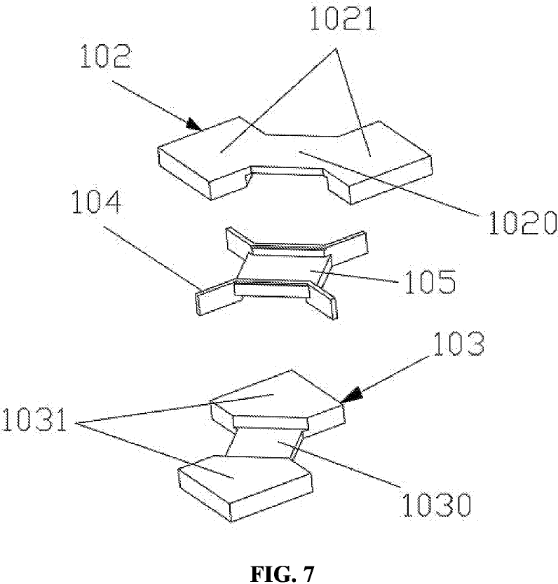

FIG. 7 is an exploded view of the bottom of the discrete component in this embodiment. The second electrode frame 102 includes a second electrode base 1020 and at least two second electrode connection portions 1021, the at least two second electrode connection portions 1021 are connected to the outer periphery of the second electrode base 1020, a height difference is configured between the surface of each second electrode connection portion 1021 facing the third electrode frame 103 and the surface of the second electrode base 1020 facing the third electrode frame 103, and empty spaces are formed between two adjacent second electrode connection portions 1021.

The third electrode frame 103 includes a third electrode base 1030 and at least two third electrode connection portions 1031, the at least two third electrode connection portions 1031 are connected to the outer periphery of the third electrode base 1030, a height difference is configured between the surface of each third electrode connection portion 1031 facing the second electrode frame 102 and the surface of the third electrode base 1030 facing the second electrode frame 102, the second electrode base 1020 is stacked on the third electrode base 1030, and the at least two third electrode connection portions 1031 are disposed in the empty spaces in a one-to-one manner.

The empty spaces are formed between the two adjacent second electrode connection portions 1021 and are configured to accommodate the third electrode connection portions 1031, and the second electrode base 1020 and the third electrode base 1030 are stacked, so that the second electrode frame 102 is mounted on the third electrode frame 103, and the second electrode frame 102 and the third electrode frame 103 form a structure having a uniform height, and the second electrode frame 102 and the third electrode frame 103 are connected on the same layer.

In this embodiment, the second electrode frame 102 includes the second electrode base 1020 and two second electrode connection portions 1021. The two second electrode connection portions 1021 are connected, one to one, to two ends of the second electrode base 1020 in opposite directions. Moreover, a height difference is configured between the lower surface of the second electrode base 1020 and the lower surface of each second electrode connection portion 1021. The empty spaces are formed between two adjacent second electrode connection portions 1021.

The third electrode frame 103 includes the third electrode base 1030 and two third electrode connection portions 1031. The two third electrode connection portions 1031 are connected, one to one, to two ends of the third electrode base 1030 in opposite directions. A height difference is configured between the upper surface of the third electrode base 1030 and the upper surface of each third electrode connection portion 1031.

The second electrode base 1020 is stacked on the third electrode base 1030. The two third electrode connection portions 1031 are disposed in the empty spaces in a one-to-one manner.

In an embodiment, a first insulating plate 104 is vertically disposed between a second electrode connection portion 1021 and a third electrode connection portion 1031 adjacent to the second electrode connection portion 1021. It can be understood that in this embodiment, a total of four first insulating plates 104 are provided.

A second insulating plate 105 is horizontally disposed between the second electrode base 1020 and the third electrode base 1030, between the first electrode frame 101 and the second electrode frame 102 and between the first electrode frame 101 and the third electrode frame 103 separately.

The first insulating plate 104 is inserted between a second electrode connection portion 1021 and a third electrode connection portion 1031 adjacent to each other so that the second electrode connection portion 1021 and the third electrode connection portion 1031 do not conduct electricity to each other and are insulated from each other. The second insulating plate 105 ensures that the electrode frames do not conduct electricity to each other and are insulated from each other.

In this embodiment, the second insulating plate 105 between the second electrode base 1020 and the third electrode base 1030 is connected to the four first insulating plates 104 and is integrally formed with the four first insulating plates 104.

The second insulating plate 105 (not shown) between the first electrode frame 101 and the second electrode frame 102 and the second insulating plate 105 (not shown) between the first electrode frame 101 and the third electrode frame 103 can be integrally formed due to being located on the same plane.

In this embodiment of the present application, both the first insulating plate 104 and the second insulating plate 105 are made of an aluminum nitride material or a silicon nitride material.

As shown in FIG. 2, the support surface 10 is provided with a moisture-proof part 100 along the peripheral edge of the support surface 10. That is, the moisture-proof part 100 extends along the peripheral edge of the upper surface of the lead frame 1 to form a quadrangle, and the support surface 10 is located within the peripheral edge of the moisture-proof part 100. The moisture-proof part can extend the path along which water vapor enters each lateral surface 11, thereby preventing the water vapor from infiltrating into the chip 2 and playing a waterproof role for the chip 2.

It is to be noted that the shape of the moisture-proof part 100 is not limited to a quadrangle. For example, the moisture-proof part 100 may also be configured to be in other shapes such as a circle, a hexagon and an octagon.

In this embodiment of the present application, the lead frame 1 is wrapped with a package 4, and the package 4 covers at least the multiple lateral surfaces 11 to seal the chip 2 within the recess 12 of each lateral surface 11. The package 4 can insulate and protect the chip 2 to increase the integrity and stability of the three-dimensional discrete component. In addition, the package 4 can fix the dispersed first electrode frame 101, second electrode frame 102 and third electrode frame 103 as a whole.

In this embodiment, the package 4 extends to each edge of the support surface 10 and fully covers the moisture-proof part 100. With such design, the strength of bonding between the package 4 and the lead frame 1 can be enhanced.

### Embodiment Five

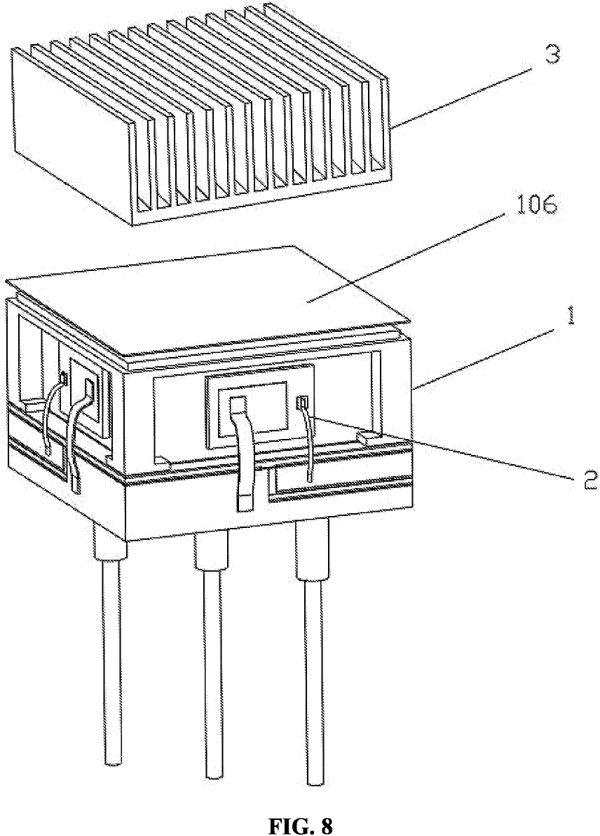

Embodiment five provides a discrete component having a heat sink. FIG. 8 is an exploded view of a discrete component according to embodiment five of the present application. As shown in FIG. 8, this embodiment is one implementation.

In an embodiment, as shown in FIG. 8, the heat sink 3 is disposed on a support surface of the lead frame. In this embodiment of the present application, the heat sink 3 includes multiple heat sink fins. The multiple heat sink fins increase the heat dissipation area. When the chip 2 heats up, heat is conducted to the lead frame 1 and then is dissipated through the heat sink 3, thereby significantly improving the heat dissipation efficiency.

It is to be noted that the heat sink 3 may also be disposed in the discrete component provided by embodiment four.

The support surface can provide a stable support for the heat sink 3. The heat sink 3 enhances the heat dissipation capability of the discrete component.

In an embodiment, the lead frame 1 and the heat sink 3 may be made of the same material. For example, the heat sink 3 may be integrally formed with the lead frame 1 when the lead frame 1 is formed. Alternatively, the lead frame 1 is bonded to the heat sink 3 by a bonding agent so that the lead frame 1 and the heat sink 3 form an integral structure.

In this embodiment of the present application, the heat sink 3 and the lead frame 1 are connected through a nano-silver sintering process.

It is to be noted that in view of the insulation requirement of the heat sink 3, a layer of third insulating plate 106 is laid on the support surface 10 of the lead frame 1. In this embodiment of the present application, the third insulating plate 106 is made of an aluminum nitride material or a silicon nitride material.

### Embodiment Six

Embodiment six provides a discrete component with a package.

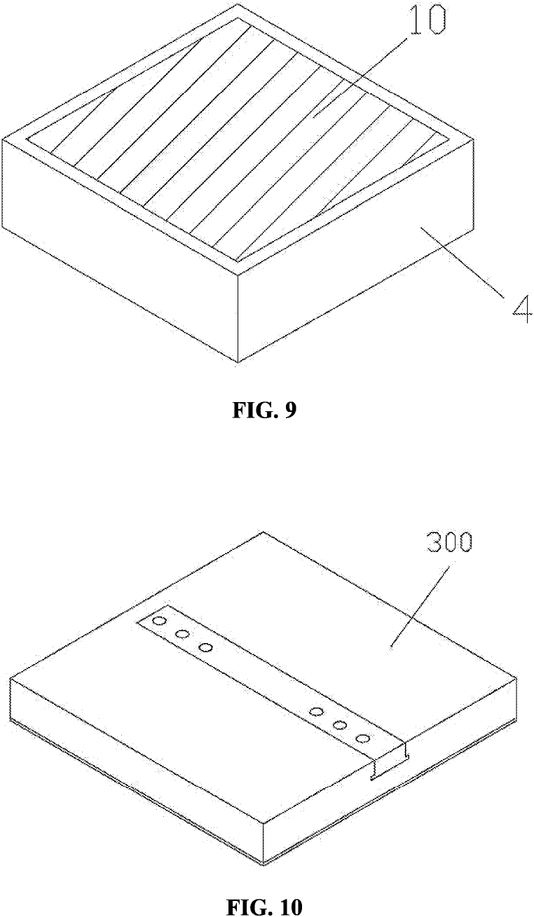

As shown in FIG. 9, the discrete component includes the lead frame 1 of any one of embodiments one to five. The lead frame 1 is wrapped with a package 4. The package 4 covers at least the multiple lateral surfaces 11 to seal the chip 2 within the recess 12 of each lateral surface 11. The package 4 can insulate and protect the chip 2 to increase the integrity and stability of the three-dimensional discrete component.

In addition, the package 4 can fix the dispersed first electrode frame 101, second electrode frame 102 and third electrode frame 103 as a whole.

In this embodiment, the package 4 extends to each edge of the support surface 10 and fully covers the moisture-proof part 100. With such design, the strength of bonding between the package 4 and the lead frame 1 can be enhanced.

It is to be noted that the heat sink 3 is at least partially exposed from the package 4.

### Embodiment Seven

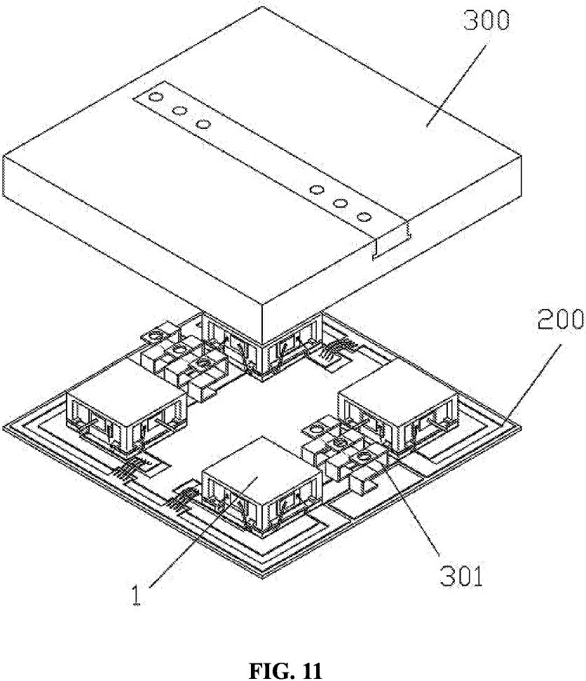

This embodiment provides a power module. As shown in FIGS. 10 and 11, the power module includes discrete components, a circuit board 200, an encapsulation housing 300, an encapsulation body and connection terminals 301.

The discrete components are as described in embodiments one to six and are not described in detail in this embodiment. The discrete components are disposed on the circuit board 200. The circuit board 200 is disposed within the encapsulation housing 300. The discrete components are built in the encapsulation housing 300. The encapsulation body is configured to pot the circuit board. The discrete components are partially exposed from the encapsulation body. The connection terminals 301 are disposed on the circuit board 200. One end of each connection terminal 301 is connected to the circuit board 200. Another end of each connection terminal 301 extends out of the encapsulation housing 300.

In this embodiment, four discrete components are disposed on the circuit board 200. The four discrete components are disposed on the circuit board 200. The encapsulation housing 300 encapsulates the four discrete components.

In the power module provided by this embodiment, chips 2 are disposed on the discrete components so that the circuit structure on the circuit board 200 is simple. In this embodiment, compared with chip mounting on a plane in the related art, the circuit board 200 occupies a smaller area, thereby simplifying the circuit structure of the circuit board 200 and increasing the density of discrete components of the power module.

### Embodiment Eight

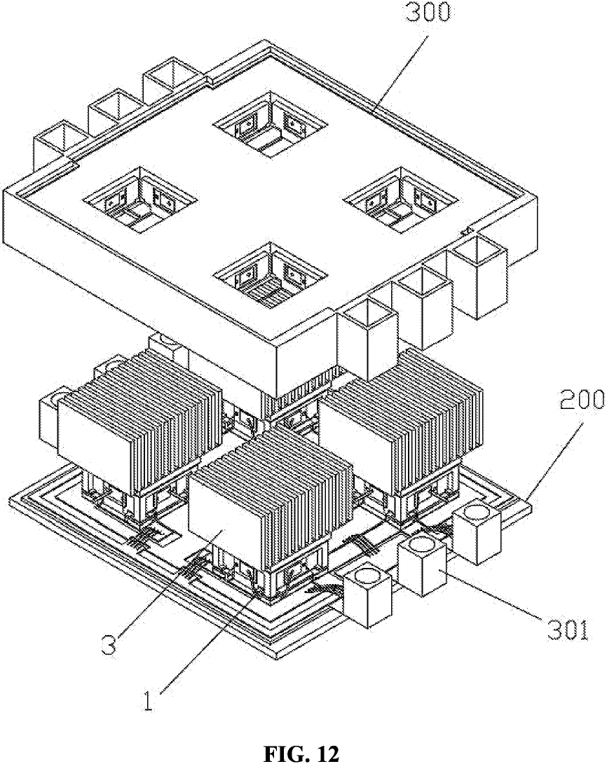

This embodiment provides a power module. As shown in FIG. 12, the power module includes discrete components, a circuit board 200, an encapsulation housing 300, an encapsulation body and connection terminals 301.

The discrete components are as described in embodiments one to six and are not be described in detail in this embodiment. The discrete components are disposed on the circuit board 200. The circuit board 200 is disposed within the encapsulation housing 300. The discrete components are built in the encapsulation housing 300. The encapsulation body is configured to pot the circuit board 200. The discrete components are partially exposed from the encapsulation body. The connection terminals 301 are disposed on the circuit board 200. One end of each connection terminal 301 is connected to the circuit board 200. Another end of each connection terminal 301 extends out of the encapsulation housing 300.

In this embodiment, the circuit board 200 is provided with four discrete components. The bottom of each of the four discrete components is disposed on the circuit board 200. The top surface of the encapsulation housing 300 is formed with four vias. The heat sinks 3 located on the top of the four discrete components protrude from the four vias in a one-to-one manner. Lead frames 1 of the four discrete components are encapsulated in the encapsulation housing 300.

In the power module provided by this embodiment, chips 2 are disposed on the discrete components so that the circuit structure on the circuit board 200 is simple. In this embodiment, compared with chip mounting on a plane in the related art, the circuit board 200 occupies a smaller area, thereby simplifying the circuit structure of the circuit board 200 and increasing the density of discrete components of the power module.

### Embodiment Nine

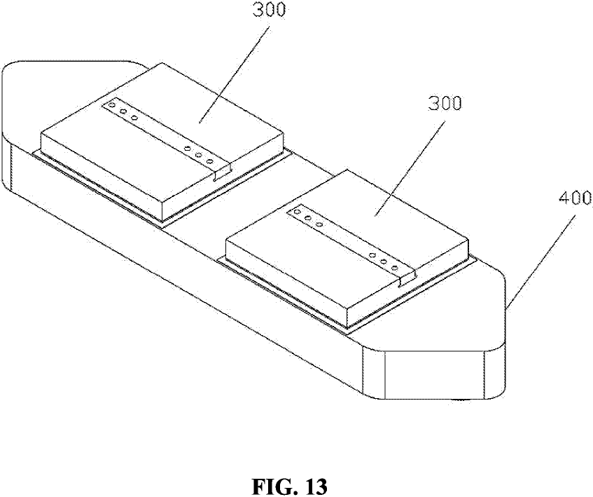

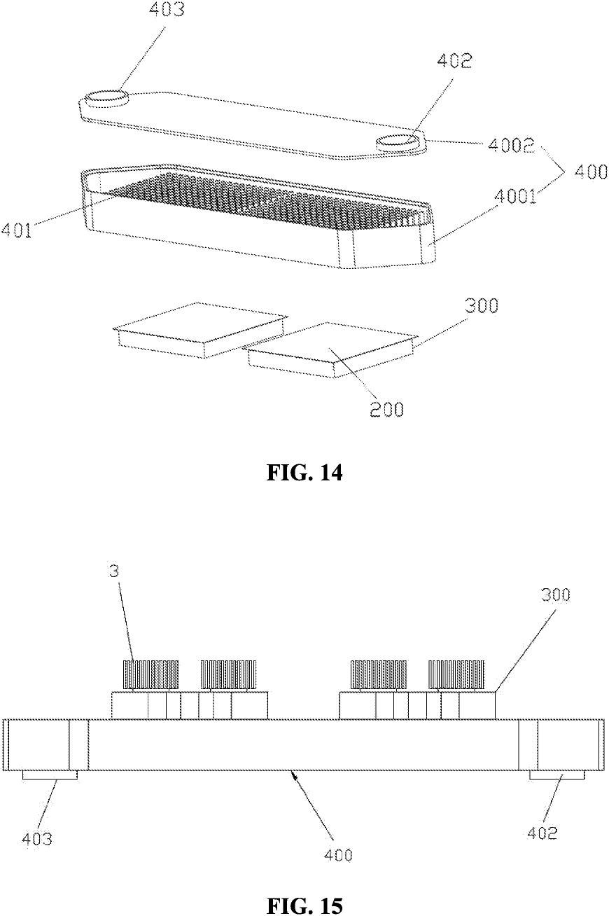

This embodiment provides a heat sink system. As shown in FIGS. 13 and 14, the heat sink system includes power modules and a heat sink assembly 400. The power modules are disposed on a surface of the heat sink assembly 400.

The power modules are as described in embodiment seven or eight and are not described in detail in this embodiment.

A heat sink chamber is disposed within the heat sink assembly 400. Several heat sink bars 401 are disposed within the heat sink chamber. An inlet 402 is disposed at one end of the heat sink chamber. An outlet 403 is disposed at another end of the heat sink chamber. A heat sink runner is defined among the heat sink bars 401 and between the inlet 402 and the outlet 403.

The power module is disposed on the heat sink assembly so that heat can be taken away from the power module, avoiding the heat from accumulating inside the power module and improving the heat dissipation effect.

As shown in FIG. 14, the heat sink assembly 400 includes a heat sink box 4001 and a cover plate 4002 detachably connected to each other. The heat sink box 4001 has a box bottom and one enclosing sidewall. The top of the heat sink box 4001 is formed with an opening. The cover plate 4002 seals the opening so that the heat sink chamber is formed. The inlet 402 and the outlet 403 are disposed on the cover plate 4002. The back of the circuit board 200 of the power modules is connected to the box bottom. In other embodiments, one or more power modules may be provided.

The inlet 402 and the outlet 403 are disposed at one end of the cover 4002 and another end of the cover 4002 respectively. The heat sink chamber is configured such that a coolant can flow through the heat sink chamber. The coolant can enter the heat sink chamber through the inlet 402, pass through the heat sink runner and then flow out of the heat sink chamber through the outlet 403, thereby taking away part of the heat from the power modules.

In the heat sink system provided in this embodiment, the power modules are disposed on the heat sink assembly 400 so that the area of contact between the power modules and the heat sink assembly 400 can be increased; the coolant can enter the heat sink chamber through the inlet 402, pass through the heat sink runner and then flow out of the heat sink chamber through the outlet 403 to take away the heat from the power modules, thereby avoiding the heat from accumulating inside the power modules, improving the heat dissipation effect, enabling the power modules to operate normally, and maintaining the working performance of the power modules; and the heat sink bars 401 are disposed inside the heat sink chamber so that the area of contact with the coolant can be increased and the heat dissipation effect can be improved.

### Embodiment Ten

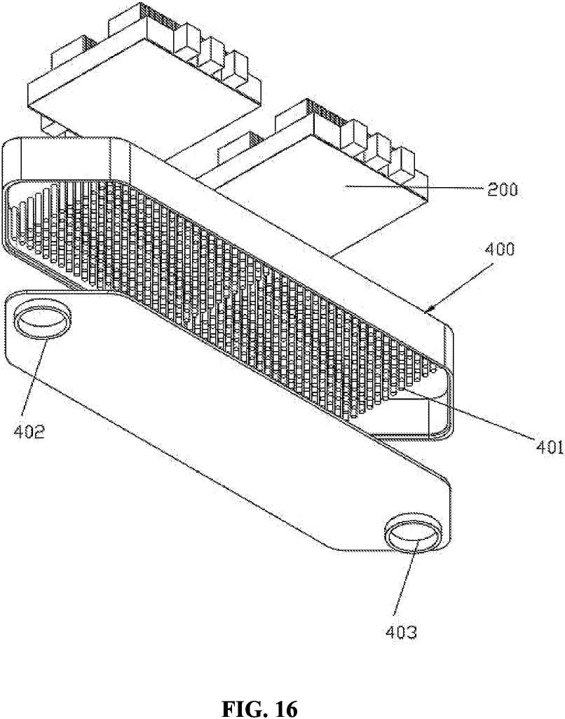

This embodiment provides a heat sink system. As shown in FIGS. 15 and 16, the heat sink system includes power modules and a heat sink assembly 400. The power modules are disposed on the heat sink assembly 400. The heat sink assembly is connected to the side of the circuit board facing away from the discrete components. In this embodiment, the power modules may dissipate heat through heat sinks 3 or through the heat sink assembly 400.

In this embodiment, the power modules are as described in embodiment seven or eight and are not described in detail in this embodiment.

A heat sink chamber is disposed within the heat sink assembly 400. Several heat sink bars 401 are disposed within the heat sink chamber. An inlet 402 is disposed at one end of the heat sink chamber. An outlet 403 is disposed at another end of the heat sink chamber. A heat sink runner is defined among the heat sink bars 401 and between the inlet 402 and the outlet 403.

Referring to FIG. 14, the heat sink assembly 400 includes a heat sink box 4001 and a cover plate 4002 detachably connected to each other. The heat sink box 4001 has a box bottom and one enclosing sidewall. The top of the heat sink box 4001 is formed with an opening. The cover plate 4002 seals the opening so that the heat sink chamber is formed. The inlet 402 and the outlet 403 are disposed on the cover plate 4002. The back of the circuit board 200 of the power modules is connected to the box bottom. In other embodiments, one or more power modules may be provided.

The inlet 402 and the outlet 403 are disposed at one end of the cover 4002 and another end of the cover 4002 respectively. The heat sink chamber is configured such that a coolant can flow through the heat sink chamber. The coolant can enter the heat sink chamber through the inlet 402, pass through the heat sink runner and then flow out of the heat sink chamber through the outlet 403, thereby taking away part of the heat from the power modules.

In the heat sink system provided in this embodiment, the power modules are disposed on the heat sink assembly 400 so that the area of contact between the power modules and the heat sink assembly 400 can be increased; the coolant can enter the heat sink chamber through the inlet 402, pass through the heat sink runner and then flow out of the heat sink chamber through the outlet 403 to take away the heat from the power modules, thereby avoiding the heat from accumulating inside the power modules, improving the heat dissipation effect, enabling the power modules to operate normally, and maintaining the working performance of the power modules; and the heat sink bars 401 are disposed inside the heat sink chamber so that the area of contact with the coolant can be increased and the heat dissipation effect can be improved.

Apparently, the preceding embodiments of the present disclosure are illustrative of the present disclosure and are not intended to limit the implementations of the present disclosure. Those of ordinary skill in the art can make various apparent modifications, adaptations, and substitutions without departing from the scope of the present disclosure. Implementations of the present application cannot be and do not need to be all exhausted herein. Any modifications, equivalent substitutions, and improvements made within the spirit and principle of the present disclosure fall within the scope of the claims of the present disclosure.

What is claimed is:

1. A discrete component, comprising:
a lead frame comprising a top and a bottom disposed adjacent to each other, wherein the top comprises a support surface and a plurality of lateral surfaces connected in sequence, and the plurality of lateral surfaces are located between the support surface and the bottom; and
a chip disposed on each of at least one lateral surface of the plurality of lateral surfaces separately.

2. The discrete component of claim 1, wherein the support surface is provided with a moisture-proof part along a peripheral edge of the support surface.

3. The discrete component of claim 1, wherein a recess is formed in the each of the at least one lateral surface, and the chip is disposed in the recess.

4. The discrete component of claim 1, wherein the top comprises a first electrode frame, and the bottom comprises a second electrode frame and a third electrode frame, wherein
the first electrode frame, the second electrode frame and the third electrode frame are insulated from each other, a first electrode of the chip is connected to the first electrode frame, a second electrode of the chip is connected to the second electrode frame, and a third electrode of the chip is connected to the third electrode frame.

5. The discrete component of claim 2, wherein the top comprises a first electrode frame, and the bottom comprises a second electrode frame and a third electrode frame, wherein
the first electrode frame, the second electrode frame and the third electrode frame are insulated from each other, a first electrode of the chip is connected to the first electrode frame, a second electrode of the chip is connected to the second electrode frame, and a third electrode of the chip is connected to the third electrode frame.

6. The discrete component of claim 3, wherein the top comprises a first electrode frame, and the bottom comprises a second electrode frame and a third electrode frame, wherein
the first electrode frame, the second electrode frame and the third electrode frame are insulated from each other, a first electrode of the chip is connected to the first electrode frame, a second electrode of the chip is connected to the second electrode frame, and a third electrode of the chip is connected to the third electrode frame.

7. The discrete component of claim 4, wherein the second electrode frame and the third electrode frame are at least partially stacked.

8. The discrete component of claim 7, wherein the second electrode frame is disposed on a surface of the third electrode frame, and the second electrode frame and the third electrode frame are each formed with a via, wherein
a first external terminal of the first electrode frame extends through both the via of the second electrode frame and the via of the third electrode frame and is exposed from the second electrode frame and the third electrode frame;
a second external terminal of the second electrode frame extends through the via of the third electrode frame and is exposed from the third electrode frame; and
a third external terminal of the third electrode frame is exposed.

9. The discrete component of claim 8, wherein the third electrode frame comprises a third electrode base and at least two third electrode connection portions disposed on the third electrode base, and two adjacent ones of the at least two third electrode connection portions are spaced apart from each other and form empty spaces on the third electrode base; and
the second electrode frame comprises at least two second electrode connection portions, and the at least two second electrode connection portions are disposed in the empty spaces in a one-to-one manner.

10. The discrete component of claim 9, wherein a first insulating plate is vertically disposed between a second electrode connection portion among the at least two second electrode connection portions and a third electrode connection portion adjacent to the second electrode connection portion; and
a second insulating plate is horizontally disposed between the first electrode frame and the second electrode frame, between the first electrode frame and the third electrode frame and between the second electrode frame and the third electrode frame separately.

11. The discrete component of claim 7, wherein the support surface is configured to be a first external terminal, a first part of the second electrode frame and a second part of the third electrode frame are arranged adjacent to each other on a same horizontal plane, a lower surface of the first part is configured to be a second external terminal, and a lower surface of the second part is configured to be a third external terminal.

12. The discrete component of claim 11, wherein the second electrode frame comprises a second electrode base and at least two second electrode connection portions, the at least two second electrode connection portions are connected to an outer periphery of the second electrode base, a height difference is configured between a surface of each of the at least two second electrode connection portions facing the third electrode frame and a surface of the second electrode base facing the third electrode frame, and empty spaces are formed between two adjacent ones of the at least two second electrode connection portions; and
the third electrode frame comprises a third electrode base and at least two third electrode connection portions, the at least two third electrode connection portions are connected to an outer periphery of the third electrode base, a height difference is configured between a surface of each of the at least two third electrode connection portions facing the second electrode frame and a surface of the third electrode base facing the second electrode frame,
wherein the second electrode base is stacked on the third electrode base, and the at least two third electrode connection portions are disposed in the empty spaces in a one-to-one manner.

13. The discrete component of claim 12, wherein a first insulating plate is vertically disposed between a second electrode connection portion among the at least two second electrode connection portions and a third electrode connection portion adjacent to the second electrode connection portion; and
a second insulating plate is horizontally disposed between the second electrode base and the third electrode base, between the first electrode frame and the second electrode frame and between the first electrode frame and the third electrode frame separately.

14. The discrete component of claim 9, wherein in a first direction defined by the each of the at least one lateral surface, the chip is adjacent to one of the at least two second electrode connection portions and one of the at least two third electrode connection portions, the second electrode of the chip is connected to an outer peripheral surface of the one of the at least two second electrode connection portions, and the third electrode of the chip is connected to an outer peripheral surface of the one of the at least two third electrode connection portions.

15. The discrete component of claim 12, wherein in a first direction defined by the each of the at least one lateral surface, the chip is adjacent to one of the at least two second electrode connection portions and one of the at least two third electrode connection portions, the second electrode of the chip is connected to an outer peripheral surface of the one of the at least two second electrode connection portions, and the third electrode of the chip is connected to an outer peripheral surface of the one of the at least two third electrode connection portions.

16. The discrete component of claim 1, wherein a heat sink is disposed on the support surface.

17. The discrete component of claim 1, further comprising:
a package covering at least the plurality of lateral surfaces.

18. A power module, comprising the discrete component of claim 1 and further comprising:
a circuit board, wherein the discrete component is disposed on the circuit board;
an encapsulation housing, wherein the circuit board is disposed within the encapsulation housing, and the discrete component is at least partially built in the encapsulation housing;
an encapsulation body configured to pot the circuit board, wherein the discrete component is partially exposed from the encapsulation body; and
a connection terminal disposed on the circuit board, wherein one end of the connection terminal is connected to the circuit board, and another end of the connection terminal extends out of the encapsulation housing.

19. A heat sink system, comprising the power module of claim 18 and further comprising:
a heat sink assembly, wherein at least one power module is disposed on the heat sink assembly, a heat sink chamber is disposed within the heat sink assembly, several heat sink bars are disposed within the heat sink chamber, an inlet is disposed at one end of the heat sink chamber, an outlet is disposed at another end of the heat sink chamber, and a heat sink runner is defined among the heat sink bars and between the inlet and the outlet.
